(19) United States
(12) Patent Application Publication
(10) Pub. No.: US 2023/0411182 A1
(43) Pub. Date: Dec. 21, 2023

(54) SUBSTRATE FIXING DEVICE

(71) Applicant: SHINKO ELECTRIC INDUSTRIES CO., LTD., Nagano-shi (JP)

(72) Inventors: Masahiro Sunohara, Nagano-shi (JP); Riku Nishikawa, Nagano-shi (JP)

(21) Appl. No.: 18/337,213

(22) Filed: Jun. 19, 2023

(30) Foreign Application Priority Data
Jun. 21, 2022 (JP) 2022-099888

(51) Int. Cl. H01L 21/67; H01L 21/683; H01L 21/687

(52) U.S. Cl. CPC H01L 21/67103; H01L 21/6833; H01L 21/68785; H01L 21/67248

(57) ABSTRACT

A substrate fixing device includes a base plate, a ceramic plate bonded to the base plate via an adhesive layer and configured to adsorb a substrate by electrostatic force, a thermal conduction member arranged in only a central region, which overlaps a central portion of the ceramic plate in a plan view, or in only an outer circumferential region, which overlaps an outer circumferential portion of the ceramic plate in a plan view of at least one of an adhesive surface of the ceramic plate, an adhesive surface of the base plate, or an inside of the adhesive layer, the thermal conduction member having thermal conductivity in a stack direction of the base plate and the ceramic plate member higher than thermal conductivity in a plane direction perpendicular to the stack direction.

### CROSS-REFERENCE TO RELATED APPLICATIONS

This application is based on and claims the benefit of priority from prior Japanese patent application No, 2022-0998H filed on Jun. 21, 2022, the entire contents of which are incorporated herein by reference.

### TECHNICAL FIELD

The present invention relates to a substrate fixing device ART

### BACKGROUND ART

In general, a substrate fixing device that adsorbs and holds a wafer when manufacturing a semiconductor component, for example, is also referred to as an electrostatic chuck (ESC), and includes a ceramic plate having an electrode embedded therein. The substrate fixing device has a structure in which the ceramic plate is bonded to a base plate, and applies a voltage to the electrode embedded in the ceramic plate, thereby adsorbing the wafer on the ceramic plate by using electrostatic force. By adsorbing and holding the wafer on the ceramic plate, processes such as microfabrication and etching on the wafer are efficiently performed.

In such a substrate fixing device, the ceramic plate is bonded to the base plate by, for example, a silicone resin-based adhesive. When the ceramic plate and the base plate are bonded by an adhesive, since the thermal resistance of the adhesive in a thickness direction is relatively large, the transfer of heat from the ceramic plate adsorbing the wafer to the base plate is inhibited, which may make it difficult to rapidly control a temperature of the wafer. Regarding this, in order to improve the heat transfer property from the ceramic plate to the base plate, a technology of bonding the ceramic plate to the base plate by an adhesive layer composed of a carbon nanotube assembly having high thermal conductivity in a longitudinal direction, instead of the adhesive, is suggested.

### CITATION LIST

Patent Literature
PTL 1: JP2021-111688A

### SUMMARY OF INVENTION

However, in recent years, as microfabrication on the wafer is progressing, it is required to locally control a temperature distribution on an adsorption surface of the ceramic plate that adsorbs the wafer. For example, it is required to control a central region and an outer circumferential region of the adsorption surface of the ceramic plate to different temperatures.

However, when the adhesive layer composed of the carbon nanotube assembly is used, heat is uniformly transferred from the entire ceramic plate to the base plate via the adhesive layer, and therefore, it is difficult to control the central region and the outer circumferential region of the adsorption surface of the ceramic plate to different temperatures. Specifically, the carbon nanotubes are arranged in the entire adhesive layer that bonds the ceramic plate and the base plate, so that the transfer of heat from the ceramic plate to the base plate is made uniform, and thus, there is a limitation in the improvement of controllability of the temperature distribution on the entire adsorption surface of the ceramic plate.

Aspect of non-limiting embodiments of the present disclosure is to provide a substrate fixing device capable of improving controllability of a temperature distribution on an adsorption surface.

According to an aspect of the present disclosure, there is provided a substrate fixing device including a base plate, a ceramic plate, and a thermal conduction member. The ceramic plate is bonded to the base plate via an adhesive layer and is configured to adsorb a substrate by electrostatic force. The thermal conduction member is arranged in only a central region, which overlaps a central portion of the ceramic plate in a plan view, or in only an outer circumferential region, which overlaps an outer circumferential portion of the ceramic plate in a plan view, of at least one of an adhesive surface of the ceramic plate, an adhesive surface of the base plate, or an inside of the adhesive layer, and has thermal conductivity in a stack direction of the base plate and the ceramic plate higher than thermal conductivity in a plane direction perpendicular to the stack direction.

According to one aspect of the substrate fixing device, it is possible to achieve the effect of improving controllability of a temperature distribution on the adsorption surface.

### BRIEF DESCRIPTION OF DRAWINGS

FIG. 1 is a perspective view showing a configuration of a substrate fixing device according to a first embodiment.

FIG. 2 is a schematic view showing a cross section of the substrate fixing device according to the first embodiment.

FIG. 3 is a plan view showing a specific example of arrangement of a thermal conduction member and a heater electrode.

FIG. 4 is a flowchart showing a manufacturing method of the substrate fixing device according of the first embodiment.

FIG. 5 shows a specific example of a ceramic plate.

FIG. 6 shows a specific example of a thermal conduction member bonding process.

FIG. 7 shows a specific example of a second adhesive applying process.

FIG. 8 shows a first modified embodiment of the substrate fixing device according to the first embodiment.

FIG. 9 shows a second modified embodiment of the substrate fixing device according to the first embodiment.

FIG. 10 shows a third modified embodiment of the substrate fixing device according to the first embodiment.

FIG. 11 is a schematic view showing a cross section of a substrate fixing device according to a second embodiment.

FIG. 12 is a plan view showing a specific example of a thermal conduction member and a heater electrode.

FIG. 13 is a flowchart showing a manufacturing method of the substrate fixing device according to the second embodiment.

FIG. 14 shows a specific example of a ceramic plate.

FIG. 15 shows a specific example a thermal conduction member bonding process.

FIG. 16 shows a first modified embodiment of the substrate fixing device according to the second embodiment.

FIG. 17 shows a second modified embodiment of the substrate fixing device according to the second embodiment.

FIG. 18 shows a third modified embodiment of the substrate fixing device according to the second embodiment.

### DESCRIPTION OF EMBODIMENTS

Hereinafter, embodiments of a substrate fixing device and a manufacturing method of a substrate fixing device disclosed by the present disclosure will be described in detail with reference to the drawings. Note that the disclosed technology is not limited to the embodiments.

### First Embodiment

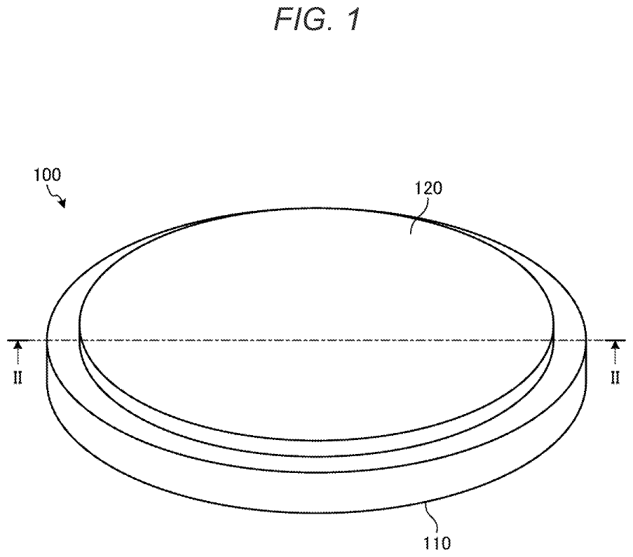

FIG. 1 is a perspective view showing a configuration of a substrate fixing device 100 according to a first embodiment. The substrate fixing device 100 shown in FIG. 1 has a structure in which a ceramic plate 120 is bonded to a base plate 110.

The base plate 110 is a circular member made of metal such as aluminum, for example. The base plate 110 is a base member for fixing the ceramic plate 120. The base plate 110 is attached to a semiconductor manufacturing apparatus, for example, and causes the substrate fixing device 100 to function as a semiconductor holding device for holding a wafer.

The ceramic plate 120 is a circular member made of insulating ceramic. A diameter of the ceramic plate 120 is smaller than a diameter of the base plate 110, and the ceramic plate 120 is fixed to a center of the base plate 110. That is, a lower surface of the ceramic plate 120 serves as an adhesive surface that is bonded to the base plate 110, and the adhesive surface is bonded to the base plate 110, so that the ceramic plate 120 is fixed. An upper surface of the ceramic plate 120 is, for example, an adsorption surface for adsorbing a target object to be adsorbed, such as a wafer.

The ceramic plate 120 has an electrically conductive electrode embedded therein, and adsorbs a target object such as a wafter to the adsorption surface by using electrostatic force that is generated when a voltage is applied to the electrode. In addition, the ceramic plate 120 has a heater electrode embedded therein, and adjusts temperatures of the ceramic plate 120 and the target object such as a wafer adsorbed on the ceramic plate 120 by the heater electrode that generates heat when a voltage is applied thereto.

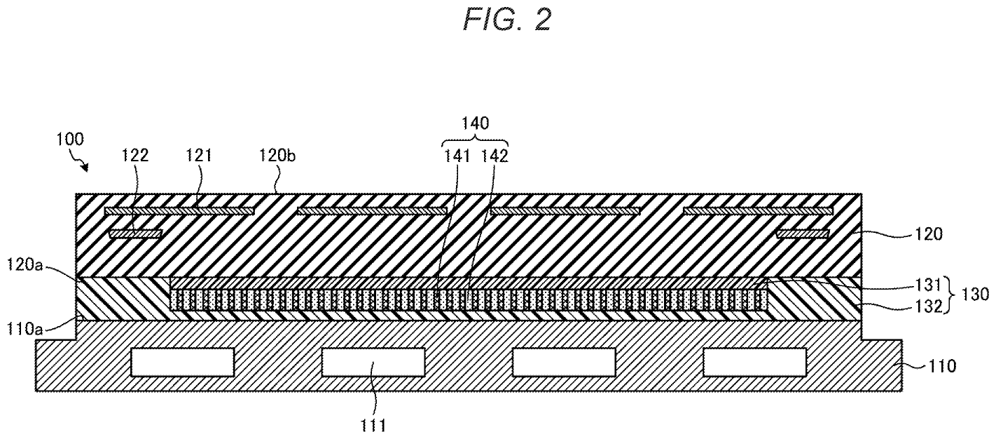

FIG. 2 is a schematic view showing a cross section of the substrate fixing device 100 according to the first embodiment. In FIG. 2, a cross section taken along a line II-II in FIG. 1 is shown. As shown in FIG. 2, the substrate fixing device 100 has a configuration in which the base plate 110 and the ceramic plate 120 are bonded by an adhesive layer 130.

The base plate 110 is a circular member made of metal and having a thickness of about 20 to 50 mm, for example. In the base plate 110, a refrigerant passage 111 serving as a passage for refrigerant such as cooling water or cooling gas is formed. The refrigerant passes through the refrigerant passage 111, so that the ceramic plate 120 is cooled. The ceramic plate 120 is cooled, so that the target object such as a wafer adsorbed on the adsorption surface of the ceramic plate 120 is cooled. An upper surface 110a of the base plate 110 is an adhesive surface bonded to the ceramic plate 120, and is bonded to a lower surface 120a of the ceramic plate 120 by the adhesive layer 130.

The ceramic plate 120 is a circular plate made of ceramic and having a thickness of 4 to 6 mm, for example. The ceramic plate 120 can be obtained by firing a green sheet fabricated using aluminum oxide, for example. The lower surface 120a of the ceramic plate 120 is an adhesive surface that is bonded to the base plate 110, and is bonded to the upper surface 110a of the base plate 110 by the adhesive layer 130. In the ceramic plate 120, an electrode 121 and a heater electrode 122 are formed.

The electrode 121 is arranged in the ceramic plate 120, and generates electrostatic force when a voltage is applied thereto. By the electrostatic force, the ceramic plate 120 adsorbs a target object such as a wafer to an upper surface 120b serving as an adsorption surface.

The heater electrode 122 is arranged below the electrode 121 in the ceramic plate 120, and generates heat when a voltage is applied thereto. Due to heat generated by the heater electrode 122, the ceramic plate 120 heats the ceramic plate 120 and the target object such as a wafer adsorbed on the upper surface 120b of the ceramic plate 120.

The adhesive layer 130 is a layer made of, for example, a silicone resin-based adhesive or an epoxy resin-based adhesive, and having a thickness of about 0.05 mm to 3.0 mm, for example, and bonds the lower surface 120a of the ceramic plate 120 to the upper surface 110a of the base plate 110. A thermal conduction member 140 is arranged in the adhesive layer 130.

The thermal conduction member 140 has a property (hereinafter, appropriately referred to as ‘thermal anisotropy’) that thermal conductivity in a stack direction of the base plate 110 and the ceramic plate 120 (which may also be simply referred to as ‘stack direction’, hereinafter) is higher than thermal conductivity in a plane direction perpendicular to the stack direction. Specifically, the thermal conduction member 140 has a structure in which a plurality of carbon nanotubes 141, each having thermal conductivity in a longitudinal direction higher than thermal conductivity in other directions, are embedded in a resin 142. The carbon nanotubes 141 are linear crystals made of carbon, and are arranged adjacent to each other such that a longitudinal direction faces toward the stack direction. In other words, the carbon nanotubes 141 are arranged adjacent to each other such that the longitudinal direction of each carbon nanotube 141 is along the stack direction. The thermal conductivity of the carbon nanotubes 141 in the longitudinal direction is higher than those of the ceramic plate 120 and adhesive layer 120. The resin 142 covers the carbon nanotubes 141 in a state in which both end surfaces of the carbon nanotubes 141 in the longitudinal direction are exposed. As the resin 142, for example, a thermosetting resin such as an epoxy resin, a thermoplastic resin such as a polyethylene resin, or the like can be used.

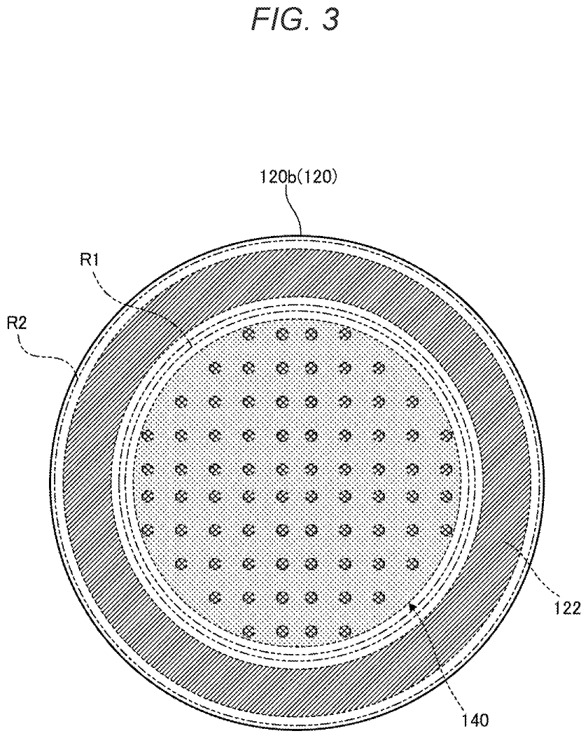

Here, a specific example of arrangement of the thermal conduction member 140 and the heater electrode 122 will be described with reference to FIG. 3, FIG. 3 is a plan view showing a specific example of arrangement of the thermal conduction member 140 and the heater electrode 140. FIG. 3 shows the arrangement of the thermal conduction member 140 and the heater electrode 122, as seen from the adsorption surface (i.e., upper surface 120b) side of the ceramic plate 120.

As shown in FIG. 3, the thermal conduction member 140 is arranged in a central region R1, which overlaps a central portion of the ceramic plate 120 in a plan view, in the inside of the adhesive layer 130 (refer to FIG. 2). The central region R1 is a disc-shaped region surrounded by an annular outer circumferential region R2, which overlaps an outer circumferential portion of the ceramic plate 120 in a plan view, in the inside of the adhesive layer 130. The thermal conduction member 140 is formed in a disc shape corresponding to the central region R1.

The thermal conduction member 140 having thermal anisotropy is arranged in the central region R1, not the entire inside of the adhesive layer 130, so that the transfer of heat from the ceramic plate 120 to the base plate 110 in the central region R1 can be locally promoted. For this reason, the temperature of the central portion of the ceramic plate 120 can be made lower than the temperature of the outer circumferential portion of the ceramic plate 120. As a result, a temperature difference between a central region and an outer circumferential region on the adsorption surface of the ceramic plate 120 can be generated, and therefore, the controllability of the temperature distribution on the adsorption surface can be improved.

In addition, as shown in FIG. 3, the heater electrode 122 is embedded in the outer circumferential portion of the ceramic plate 120. The heater electrode 122 is formed in an annular shape surrounding the central portion of the ceramic plate 120, for example, and does not overlap the thermal conduction member 140 arranged in the central region R1 inside the adhesive layer 130 in a plan view. The heating by the heater electrode 122 embedded in the outer circumferential portion of the ceramic plate 120 can adjust the temperature of the outer circumferential portion of the ceramic plate 120, resulting in an increase in the temperature difference between the central portion of the ceramic plate 120 and the outer circumferential portion of the ceramic plate 120. As a result, the temperature difference between the central region and the outer circumferential region on the adsorption surface of the ceramic plate 120 can be increased, and therefore, the controllability of the temperature distribution on the adsorption surface can be further improved.

Description will return to FIG. 2. The adhesive layer 130 has a first adhesive 131 and a second adhesive 132. The first adhesive 131 has a disc shape and bonds the disc-shaped thermal conduction member 140 to the adhesive surface (i.e., lower surface 120a) of the ceramic plate 120. The second adhesive 132 is stacked between the adhesive surface (i.e., upper surface 110a) of the base plate 110 and the adhesive surface (i.e., lower surface 120a) of the ceramic plate 120, and covers the thermal conduction member 140 and the first adhesive 131. The second adhesive 132 may be made of the same resin as a resin constituting the first adhesive 131 or may be made of a resin different from the resin constituting the first adhesive 131. In this way, the thermal conduction member 140 is bonded to the lower surface 120a of the ceramic plate 120 via the first adhesive 131, and the thermal conduction member 140 and the first adhesive 131 are covered with the second adhesive 132, so that the position of the thermal conduction member 140 is fixed in the adhesive layer 130. Thereby, the thermal conduction member 140 can be arranged in the inside of the adhesive layer 130 through a simple process, and therefore, the manufacturing efficiency of the substrate fixing device 100 can be improved.

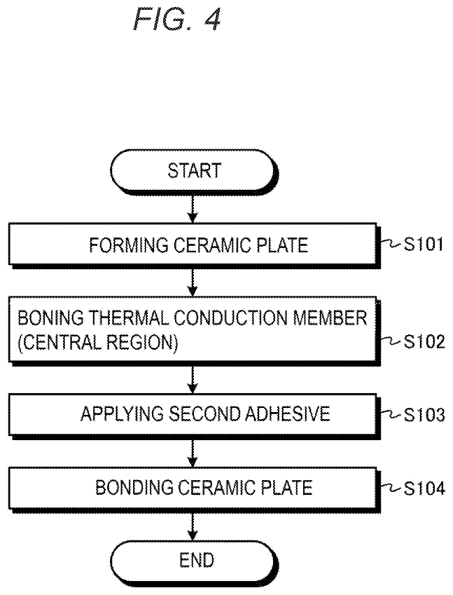

Next, a manufacturing method of the substrate fixing device 100 configured as described above will be described with reference to FIG. 4. FIG. 4 is a flowchart showing a manufacturing method of the substrate fixing device 100 according of the first embodiment.

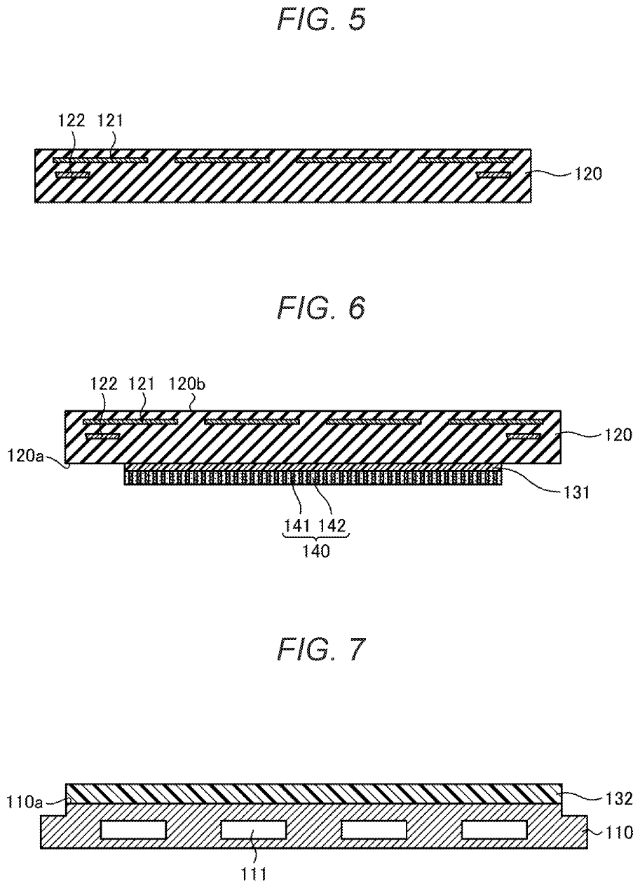

First, a ceramic plate 120 for adsorbing a target object such as a wafer is formed (step S101). Specifically, a plurality of green sheets made of, for example, aluminum oxide as a main material are fabricated. An electrode 121 is appropriately formed on one surface of the green sheet, and a heater electrode 122 is formed on one surface of another green sheet. The electrode 121 and the heater electrode 122 may be each formed by screen printing a metal paste on the surface of the green sheet, for example. Then, the ceramic plate 120 is formed by stacking and firing the plurality of green sheets. The ceramic plate 120 has a layer of the electrode 121 and a layer of the heater electrode 122 embedded therein, as shown in FIG. 5, for example. FIG. 5 shows a specific example of the ceramic plate 120. The electrode 121 is embedded in the central portion and outer circumferential portion of the ceramic plate 120, and the heater electrode 122 is embedded only in the outer circumferential portion of the ceramic plate 120. Note that, if necessary, the heater electrode 122 may be omitted.

When the ceramic plate 120 is formed, a thermal conduction member 140 is bonded to a central region of an adhesive surface (i.e., lower surface 120a) of the ceramic plate 120 overlapping a central portion of the ceramic plate 120 in a plan view (step S102). Specifically, for example, as shown in FIG. 6, the disc-shaped thermal conduction member 140 having a diameter smaller than that of the ceramic plate 120 is bonded to the central region of the lower surface 120a of the ceramic plate 120 via a first adhesive 131. FIG. 6 shows a specific example of a thermal conduction member bonding process. At the point of time when the thermal conduction member 140 is bonded, the resin constituting the first adhesive 131 is in a semi-cured state. The thermal conduction member 140 is bonded to the lower surface 120a of the ceramic plate 120 such that a longitudinal direction of the carbon nanotubes 141 coincides with the stack direction of a base plate 110 and the ceramic plate 120 (in other words, a thickness direction of the ceramic plate 120). At this time, the carbon nanotubes 141 penetrate through the resin 142 in the thickness direction, upper end surfaces of the carbon nanotubes 141 are in contact with the first adhesive 131, and lower end surfaces of the carbon nanotubes 141 are exposed from a lower surface of the resin 142.

In addition, when the resin constituting the first adhesive 131 and the resin constituting the second adhesive 132 are different, the first adhesive 131 preferably has thermal conductivity higher than that of the second adhesive 132. This makes it possible to smoothly transfer heat from the ceramic plate 120 to the thermal conduction member 140.

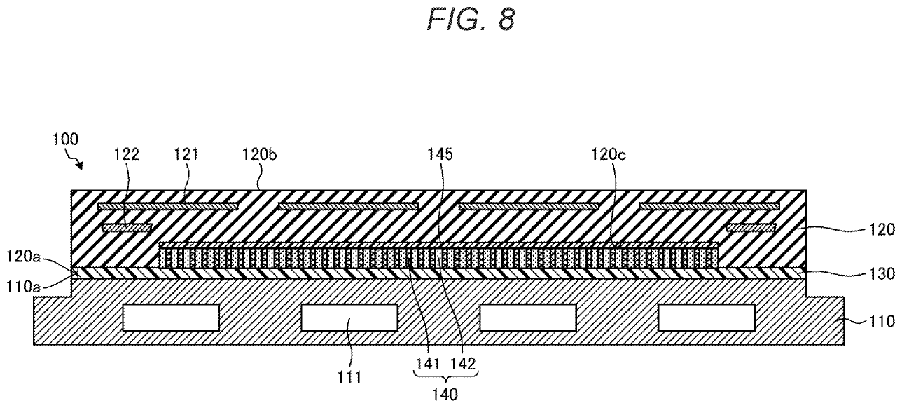

Then, a second adhesive is applied to an adhesive surface (i.e., upper surface 110a) of the base plate 110 (step S103). Specifically, for example, as shown in FIG. 7, the second adhesive 132 is applied to the entire surface of the upper surface 110a of the base plate 110. FIG. 7 shows a specific example of a second adhesive applying process. At the point of time when the second adhesive 132 is applied to the entire surface of the upper surface 110a of the base plate 110, the resin constituting the second adhesive 132 is in a semi-cured state.

When the second adhesive 132 is applied, the ceramic plate 120 is bonded to the base plate 110 by an adhesive layer 130 composed of the first adhesive 131 and the second adhesive 132 and covering the thermal conduction member 140 (step S104). The second adhesive 132 in a semi-cured state is stacked on the lower surface 120a of the ceramic plate 120 to cover the thermal conduction member 140 and the first adhesive 131, and the first adhesive 131 and the second adhesive 132 are cured by heating and pressurization. As a result, the thermal conduction member 140 is arranged in the central region R1 in the inside of the adhesive layer 130 composed of the first adhesive 131 and the second adhesive 132, and the lower surface 120a of the ceramic plate 120 is bonded to the upper surface 110a of the base plate 110 by the adhesive layer 130. At this time, the lower end surfaces of the carbon nanotubes 141 exposed from the lower surface of the resin 142 are connected to the upper surface 110a of the base plate 110 via the second adhesive 132, and therefore, are in thermally conductive communication with the upper surface 110a of the base plate 110. This makes it possible to smoothly transfer heat from the ceramic plate 120 to the base plate 110. The ceramic plate 120 is bonded to the base plate 110, so that the substrate fixing device 100 is completed. Note that the upper and lower end surfaces of the carbon nanotubes 141 may be buried in the resin 142 or the adhesive layer 130.

As described above, a substrate fixing device (e.g., substrate fixing device 100) according to the first embodiment includes a base plate (e.g., base plate 110), a ceramic plate (e.g., ceramic plate 120), and a thermal conduction member (e.g., thermal conduction member 140). The ceramic plate is bonded to the base plate via an adhesive layer (e.g., adhesive layer 130), and adsorbs a substrate by electrostatic force. The thermal conduction member is arranged in a central region (e.g., central region R1) in the inside of the adhesive layer overlapping a central portion of the ceramic plate in a plan view, and has thermal conductivity in a stack direction of the base plate and the ceramic plate higher than thermal conductivity in a plane direction perpendicular to the stack direction. Thereby, according to the substrate fixing device of the first embodiment, the controllability of the temperature distribution on the adsorption surface can be improved.

Further, the thermal conduction member may include carbon nanotubes (e.g., carbon nanotubes 141) and a resin (e.g., resin 142). The carbon nanotubes may be arranged such that the longitudinal direction faces toward the stack direction. In other words, the carbon nanotubes may be arranged such that the longitudinal direction of each carbon nanotube is along the stack direction. The resin may cover the carbon nanotubes in a state in which both end surfaces of the carbon nanotubes in the longitudinal direction are exposed. Thereby, according to the substrate fixing device of the first embodiment, it is possible to smoothly transfer heat along the stack direction of the base plate and the ceramic plate.

In addition, the adhesive layer may include a first adhesive (for example, first adhesive 131) and a second adhesive (for example, second adhesive 132). The first adhesive bonds the thermal conduction member to the central region of the ceramic plate. The second adhesive is stacked between the adhesive surface of the base plate and the adhesive surface of the ceramic plate, and covers the thermal conduction member and the first adhesive. Thereby, according to the substrate fixing device of the first embodiment, the thermal conduction member can be arranged in the inside of the adhesive layer through a simple process, and therefore, the manufacturing efficiency of the substrate fixing device can be improved.

In addition, the first adhesive may have thermal conductivity higher than that of the second adhesive. Thereby, according to the substrate fixing device of the first embodiment, it is possible to smoothly transfer heat from the ceramic plate to the thermal conduction member.

Note that, in the present embodiment, the case where the thermal conduction member 140 is arranged in the inside of the adhesive layer 130 has been described as an example, but the arrangement of the thermal conduction member 140 is not limited thereto and can be appropriately changed.

FIG. 8 shows a first modified embodiment of the substrate fixing device 100 according to the first embodiment. In FIG. 8, the same parts as those in FIG. 2 are denoted with the same reference signs.

In the modified embodiment shown in FIG. 8, the thermal conduction member 140 is arranged in a central region of the adhesive surface (i.e., lower surface 120a) of the ceramic plate 120 overlapping the central portion of the ceramic plate 120 in a plan view, instead of the central region R1 in the inside of the adhesive layer 130. Specifically, a concave portion 120c is formed in the central region of the lower surface 120a of the ceramic plate 120, and the thermal conduction member 140 is arranged in the concave portion 120c. The thermal conduction member 140 may be bonded to a bottom surface of the concave portion 120c via an adhesive 145, for example. In this way, even when the thermal conduction member 140 is arranged in the central region of the lower surface 120a of the ceramic plate 120, the temperature difference between the central region and the outer circumferential region on the adsorption surface of the ceramic plate 120 can be generated, and therefore, the controllability of the temperature distribution on the adsorption surface can be improved.

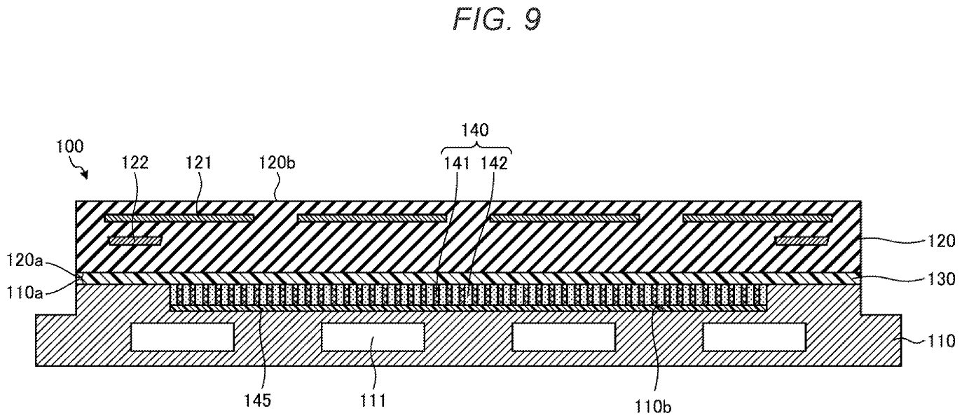

FIG. 9 shows a second modified embodiment of the substrate fixing device 100 according to the first embodiment. In FIG. 9, the same parts as those in FIG. 2 are denoted with the same reference signs.

In the modified embodiment shown in FIG. 9, the thermal conduction member 140 is arranged in a central region of the adhesive surface (i.e., upper surface 110a) of the base plate 110 overlapping the central portion of the ceramic plate 120 in a plan view, instead of the central region R1 in the inside of the adhesive layer 130. Specifically, a concave portion 110b is formed in the central region of the upper surface 110a of the base plate 110, and the thermal conduction member 140 is arranged in the concave portion 110b. The thermal conduction member 140 may be bonded to a bottom surface of the concave portion 110b via an adhesive 145, for example. In this way, even when the thermal conduction member 140 is arranged in the central region of the upper surface 110a of the base plate 110, the temperature difference between the central region and the outer circumferential region on the adsorption surface of the ceramic plate 120 can be generated, and therefore, the controllability of the temperature distribution on the adsorption surface can be improved.

In the present embodiment, the case where the entire surface of the resin 142 of the thermal conduction member 140 is covered with the adhesive layer 130 has been described as an example, but only a side surface of the resin 142 may also be covered with the adhesive layer 130.

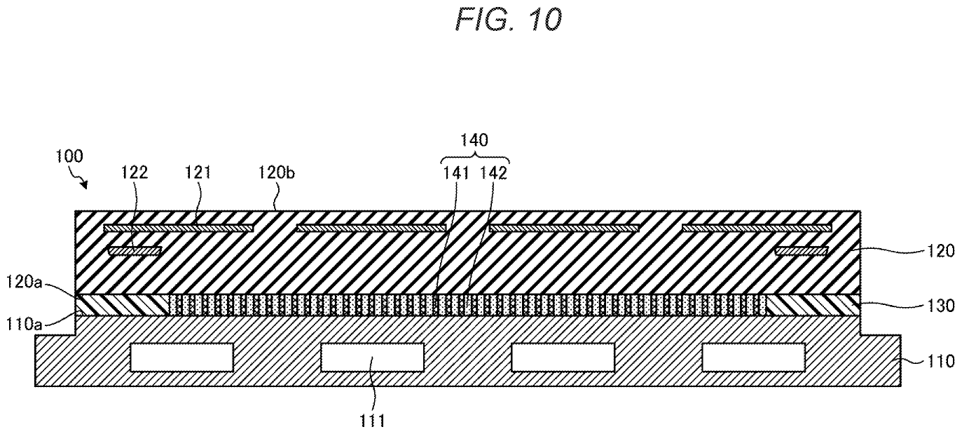

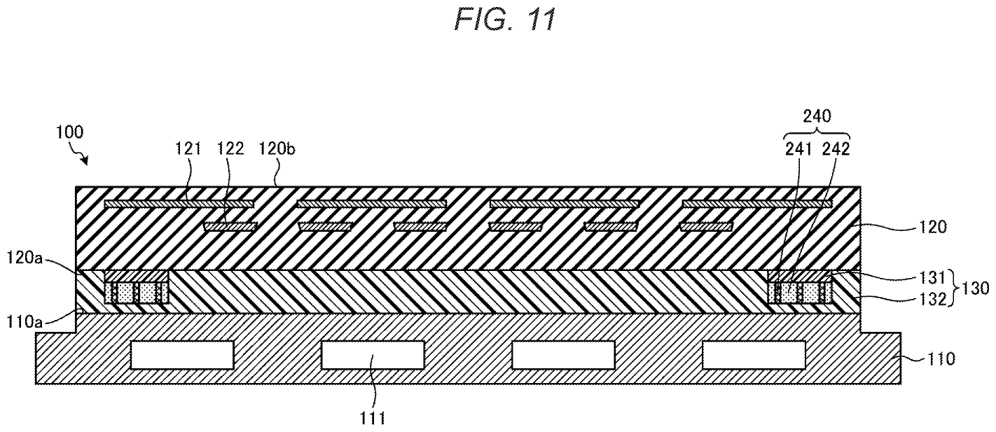

FIG. 10 shows a third modified embodiment of the substrate fixing device 100 according to the first embodiment. In FIG. 10, the same parts as those in FIG. 2 are denoted with the same reference signs.

In the modified embodiment shown in FIG. 10, only the side surface of the resin 142 of the thermal conduction member 140 is covered with the adhesive layer 130, and an upper surface (an example of the first surface) and a lower surface (an example of the second surface) of the resin 142 are exposed from the adhesive layer 130. The upper surface of the resin 142 exposed from the adhesive layer 130 is bonded to the adhesive surface (i.e., lower surface 120a) of the ceramic plate 120, and the lower surface of the resin 142 exposed from the adhesive layer 130 is bonded to the adhesive surface (i.e., upper surface 110a) of the base plate 110. The carbon nanotubes 141 of the thermal conduction member 140 have the upper end surfaces exposed from the upper surface of the resin 142 and are thus in contact with the lower surface 120a of the ceramic plate 120, and have the lower end surfaces exposed from the lower surface of the resin 142 and are thus in contact with the upper surface 110a of the base plate 110. This makes it possible to smoothly transfer heat from the ceramic plate 120 to the base plate 110 via the thermal conduction member 140, resulting in further improvement in the controllability of the temperature distribution on the adsorption surface of the ceramic plate 120.

Note that, in the first embodiment and the respective modified embodiments thereof, the case where the thermal conduction member 140 is arranged in the adhesive surface of the ceramic plate 120, the adhesive surface of the base plate 110, or the inside of the adhesive layer 130 has been described as an example. However, the arrangement position of the thermal conduction member 140 can be changed as appropriate. For example, the thermal conduction member 140 may be arranged in any two of the adhesive surface of the ceramic plate 120, the adhesive surface of the base plate 110, and the inside of the adhesive layer 130. Further, the thermal conduction member 140 may be arranged in the adhesive surface of the ceramic plate 120, the adhesive surface of the base plate 110, and the inside of the adhesive layer 130. In short, the thermal conduction member 140 may be arranged in at least one of the adhesive surface of the ceramic plate 120, the adhesive surface of the base plate 110, and the inside of the adhesive layer 130.

### Second Embodiment

A second embodiment is different from the first embodiment, in terms of the arrangement of the thermal conduction member and the heater electrode.

FIG. 11 is a schematic view showing a cross section of the substrate fixing device 100 according to the second embodiment. In FIG. 11, the same parts as those in FIG. 2 are denoted with the same reference signs. The substrate holding device 100 shown in FIG. 11 has a thermal conduction member 240, instead of the thermal conduction member 140.

The thermal conduction member 240 is arranged in the inside of the adhesive 130. The thermal conduction member 240 has thermal anisotropy similar to the thermal conduction member 140. Specifically, the thermal conduction member 240 has a structure in which a plurality of carbon nanotubes 241, each having thermal conductivity in a longitudinal direction higher than thermal conductivity in other directions, are embedded in a resin 242. The carbon nanotubes 241 are linear crystals made of carbon, and are arranged adjacent to each other such that a longitudinal direction faces toward the stack direction. In other words, the carbon nanotubes 241 are arranged adjacent to each other such that a longitudinal direction of each carbon nanotube 241 is along the stack direction. The thermal conductivity of the carbon nanotubes 241 in the longitudinal direction is higher than those of the ceramic plate 120 and adhesive layer 120. The resin 242 covers the carbon nanotubes 241 in a state in which both end surfaces of the carbon nanotubes 241 in the longitudinal direction are exposed. As the resin 242, for example, a thermosetting resin such as an epoxy resin, a thermoplastic resin such as a polyethylene resin, or the like can be used.

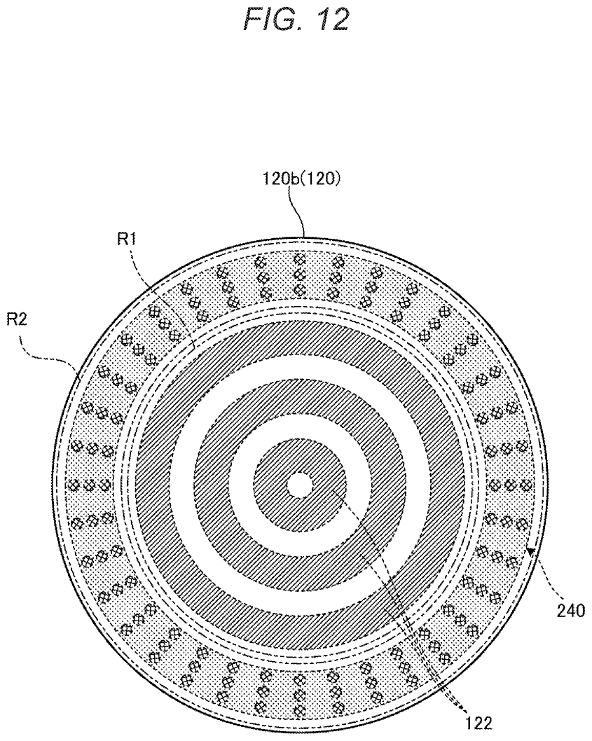

In addition, a specific example of arrangement of the thermal conduction member 240 and the heater electrode 140 will be described with reference to FIG. 12. FIG. 12 is a plan view showing a specific example of arrangement of the thermal conduction member 240 and the heater electrode 140. FIG. 12 shows the arrangement of the thermal conduction member 240 and the heater electrode 122, as seen from the adsorption surface (i.e., upper surface 120b) side of the ceramic plate 120.

As shown in FIG. 12, the thermal conduction member 240 is arranged in the outer circumferential region R2 inside the adhesive layer 130 (refer to FIG. 11) overlapping the outer circumferential portion of the ceramic plate 120 in a plan view. The outer circumferential region R2 is an annular region surrounding the disc-shaped central region R1, which overlaps the central portion of the ceramic plate 120, in the inside of the adhesive layer 130. The thermal conduction member 240 is formed in an annular shape corresponding to the outer circumferential region R2.

The thermal conduction member 240 having thermal anisotropy is arranged in the outer circumferential region R2, not the entire inside of the adhesive layer 130, so that the transfer of heat from the ceramic plate 120 to the base plate 110 in the outer circumferential region R2 can be locally promoted. For this reason, the temperature of the outer circumferential portion of the ceramic plate 120 can be made lower than the temperature of the central portion of the ceramic plate 120. As a result, the temperature difference between the central region and the outer circumferential region on the adsorption surface of the ceramic plate 120 can be generated, and therefore, the controllability of the temperature distribution on the adsorption surface can be improved.

In addition, as shown in FIG. 12, the heater electrode 122 is embedded in the central portion of the ceramic plate 120. The heater electrode 122 is formed, for example, in a shape of a triple concentric circle having a diameter smaller than that of the annular thermal conduction member 240, and does not overlap the thermal conduction member 240 arranged in the outer circumferential region R2 inside the adhesive layer 130 in a plan view. The heating by the heater electrode 122 embedded in the central portion of the ceramic plate 120 can adjust the temperature of the central portion of the ceramic plate 120, resulting in an increase in the temperature difference between the central portion of the ceramic plate 120 and the outer circumferential portion of the ceramic plate 120. As a result, the temperature difference between the central region and the outer circumferential region on the adsorption surface of the ceramic plate 120 can be increased, and therefore, the controllability of the temperature distribution on the adsorption surface can be further improved.

Description will return to FIG. 11. The adhesive layer 130 has a first adhesive 131 and a second adhesive 132. The first adhesive 131 has an annular shape and bonds the disc-shaped thermal conduction member 240 to the adhesive surface (i.e., lower surface 120a) of the ceramic plate 120. The second adhesive 132 is stacked between the adhesive surface (i.e., upper surface 110a) the base plate 110 and the adhesive surface (i.e., lower surface 120a) of the ceramic plate 120, and covers the thermal conduction member 240 and the first adhesive 131, The second adhesive 132 may be made of the same resin as a resin constituting the first adhesive 131 or may be made of a resin different from the resin constituting the first adhesive 131. In this way, the thermal conduction member 240 is bonded to the lower surface 120a of the ceramic plate 120 via the first adhesive 131, and the thermal conduction member 240 and the first adhesive 131 are covered with the second adhesive 132, so that the position of the thermal conduction member 240 is fixed in the adhesive layer 130. Thereby, the thermal conduction member 240 can be arranged in the inside of the adhesive layer 130 through a simple process, and therefore, the manufacturing efficiency of the substrate fixing device 100 can be improved.

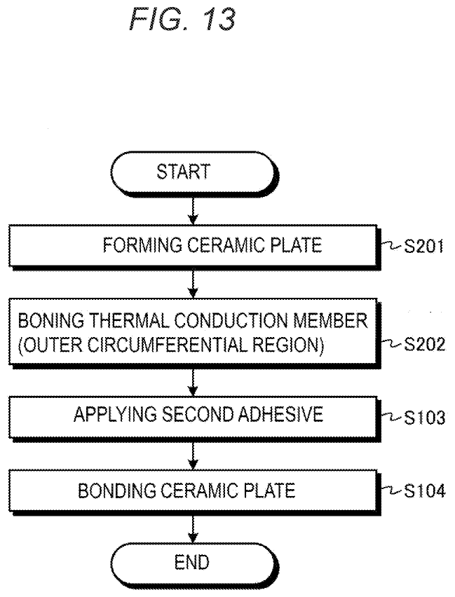

Next, a manufacturing method of the substrate fixing device 100 configured as described above will be described with reference to FIG. 13, FIG. 13 is a flowchart showing a manufacturing method of the substrate fixing device 100 according to the second embodiment. Note that, in FIG. 13, the same parts as those in FIG. 4 are denoted with the same reference signs.

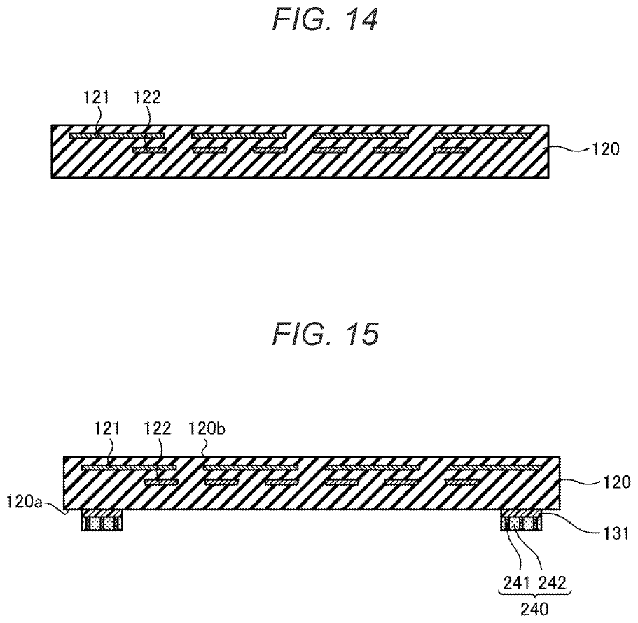

First, the ceramic plate 120 for adsorbing a target object such as a wafer is formed (step S201). Specifically, a plurality of green sheets made of, for example, aluminum oxide as a main material are fabricated. The electrode 121 is appropriately formed on one surface of the green sheet, and the heater electrode 122 is formed on one surface of another green sheet. The electrode 121 and the heater electrode 122 may be each formed by screen printing a metal paste on the surface of the green sheet, for example. Then, the ceramic plate 120 is formed by stacking and firing the plurality of green sheets. The ceramic plate 120 has a layer of the electrode 121 and a layer of the heater electrode 122 embedded therein, as shown in FIG. 14, for example. FIG. 14 shows a specific example of the ceramic plate 120, The electrode 121 is embedded in the central portion and outer circumferential portion of the ceramic plate 120, and the heater electrode 122 is embedded only in the central portion of the ceramic plate 120. Note that, if necessary, the heater electrode 122 may be omitted.

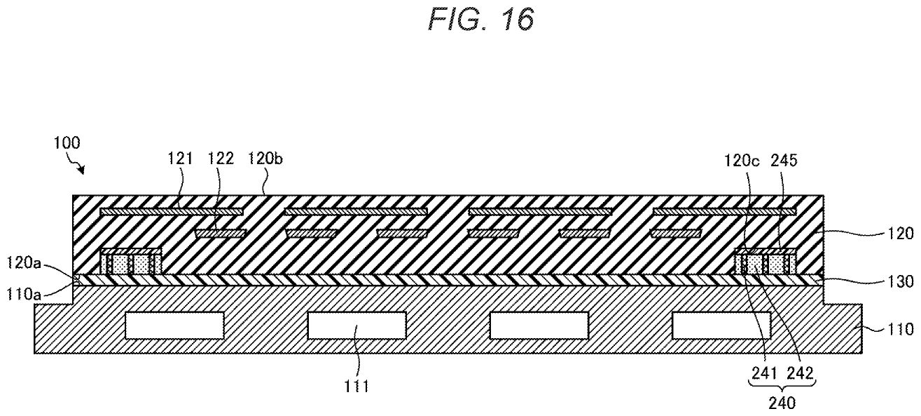

When the ceramic plate 120 is formed, the thermal conduction member 240 is bonded to the outer circumferential region of the adhesive surface (i.e., lower surface 120a) of the ceramic plate 120 overlapping the outer circumferential portion of the ceramic plate 120 in a plan view (step S202). Specifically, for example, as shown in FIG. 15, the annular thermal conduction member 240 having a diameter smaller than that of the ceramic plate 120 is bonded to the outer circumferential region of the lower surface 120a of the ceramic plate 120 via the first adhesive 131, FIG. 15 shows a specific example of a thermal conduction member bonding process. At the point of time when the thermal conduction member 240 is bonded, the resin constituting the first adhesive 131 is in a semi-cured state. The thermal conduction member 240 is bonded to the lower surface 120a of the ceramic plate 120 such that the longitudinal direction of the carbon nanotubes 241 coincides with the stack direction of the base plate 110 and the ceramic plate 120 (in other words, the thickness direction of the ceramic plate 120). At this time, the carbon nanotubes 241 penetrate through the resin 242 in the thickness direction, the upper end surfaces of the carbon nanotubes 241 are in contact with the first adhesive 131, and the lower end surfaces of the carbon nanotubes 241 are exposed from the lower surface of the resin 242.

In addition, when the resin constituting the first adhesive 131 and the resin constituting the second adhesive 132 are different, the first adhesive 131 preferably has thermal conductivity higher than that of the second adhesive 132. This makes it possible to smoothly transfer heat the ceramic plate 120 to the thermal conduction member 240.

Then, the second adhesive is applied to the adhesive surface (i.e., upper surface 110a) of the base plate 110 (step S103). Specifically, the second adhesive 132 is applied to the entire surface of the upper surface 110a of the base plate 110. At the point of time when the second adhesive 132 is applied to the entire surface of the upper surface 110a of the base plate 110, the resin constituting the second adhesive 132 is in a semi-cured state.

When the second adhesive 132 is applied, the ceramic plate 120 is bonded to the base plate 110 by the adhesive layer 130 composed of the first adhesive 131 and the second adhesive 132 and covering the thermal conduction member 240 (step S104). The second adhesive 132 in a semi-cured state is stacked on the lower surface 120a of the ceramic plate 120 to cover the thermal conduction member 240 and the first adhesive 131, and the first adhesive 131 and the second adhesive 132 are cured by heating and pressurization. As a result, the thermal conduction member 240 is arranged in the outer circumferential region R2 in the inside of the adhesive layer 130 composed of the first adhesive 131 and the second adhesive 132, and the lower surface 120a of the ceramic plate 120 is bonded to the upper surface 110a of the base plate 110 by the adhesive layer 130. At this time, the lower end surfaces of the carbon nanotubes 241 exposed from the lower surface of the resin 242 are connected to the upper surface 110a of the base plate 110 via the second adhesive 132, and therefore, are in thermally conductive communication with the upper surface 110a of the base plate 110. This makes it possible to smoothly transfer heat from the ceramic plate 120 to the base plate 110. The ceramic plate 120 is bonded to the base plate 110, so that the substrate fixing device 100 is completed. Note that the upper and lower end surfaces of the carbon nanotubes 241 may be buried in the resin 242 or the adhesive layer 130.

As described above, a substrate fixing device (e.g., substrate fixing device 100) according to the second embodiment includes a base plate (e.g., base plate 110), a ceramic plate (e.g., ceramic plate 120), and a thermal conduction member (e.g., thermal conduction member 240). The ceramic plate is bonded to the base plate via an adhesive layer (e.g., adhesive layer 130), and adsorbs a substrate by electrostatic force. The thermal conduction member is arranged in an outer circumferential region (e.g., outer circumferential region R2) in the inside of the adhesive layer overlapping an outer circumferential portion of the ceramic plate in a plan view, and has thermal conductivity in a stack direction of the base plate and the ceramic plate higher than thermal conductivity in a plane direction perpendicular to the stack direction. Thereby, according to the substrate fixing device of the second embodiment, the controllability of the temperature distribution on the adsorption surface can be improved.

Further, the thermal conduction member may include carbon nanotubes (e.g., carbon nanotubes 241) and a resin (e.g., resin 242). The carbon nanotubes may be arranged such that the longitudinal direction faces toward the stack direction. The carbon nanotubes may be arranged such that the longitudinal direction of each carbon nanotube is along the stack direction. The resin may cover the carbon nanotubes in a state in which both end surfaces of the carbon nanotubes in the longitudinal direction are exposed. Thereby, according to the substrate fixing device of the second embodiment, it is possible to smoothly transfer heat along the stack direction of the base plate and the ceramic plate.

In addition, the adhesive layer may include a first adhesive (for example, first adhesive 131) and a second adhesive (for example, second adhesive 132). The first adhesive bonds the thermal conduction member to the outer circumferential region of the adhesive surface of the ceramic plate. The second adhesive is stacked between the adhesive surface of the base plate and the adhesive surface of the ceramic plate, and covers the thermal conduction member and the first adhesive. Thereby, according to the substrate fixing device according to the second embodiment, the thermal conduction member can be arranged in the inside of the adhesive layer through a simple process, and therefore, the manufacturing efficiency of the substrate fixing device can be improved.

In addition, the first adhesive may have thermal conductivity higher than that of the second adhesive. Thereby, according to the substrate fixing device according to the second embodiment, it is possible to smoothly transfer heat from the ceramic plate to the thermal conduction member.

Note that, in the present embodiment, the case where the thermal conduction member 240 is arranged in the inside of the adhesive layer 130 has been described as an example, but the arrangement of the thermal conduction member 240 is not limited thereto and can be appropriately changed.

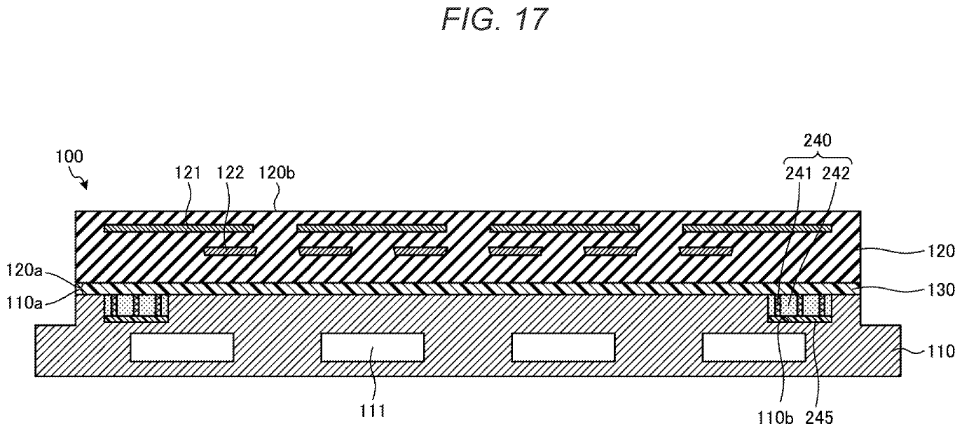

FIG. 16 shows a first modified embodiment of the substrate fixing device 100 according to the second embodiment. In FIG. 16, the same parts as those in FIG. 11 are denoted with the same reference signs.

In the modified embodiment shown in FIG. 16, the thermal conduction member 240 is arranged in an outer circumferential region of the adhesive surface (i.e., lower surface 120a) of the ceramic plate 120 overlapping the outer circumferential portion of the ceramic plate 120 in a plan view, instead of the outer circumferential region R2 in the inside of the adhesive layer 130. Specifically, a concave portion 120c is formed in the outer circumferential region of the lower surface 120a of the ceramic plate 120, and the thermal conduction member 240 is arranged in the concave portion 120c. The thermal conduction member 240 may be bonded to a bottom surface of the concave portion 120c via an adhesive 245, for example. In this way, even when the thermal conduction member 240 is arranged in the outer circumferential region of the lower surface 120a of the ceramic plate 120, the temperature difference between the central region and the outer circumferential region on the adsorption surface of the ceramic plate 120 can be generated, and therefore, the controllability of the temperature distribution on the adsorption surface can be improved.

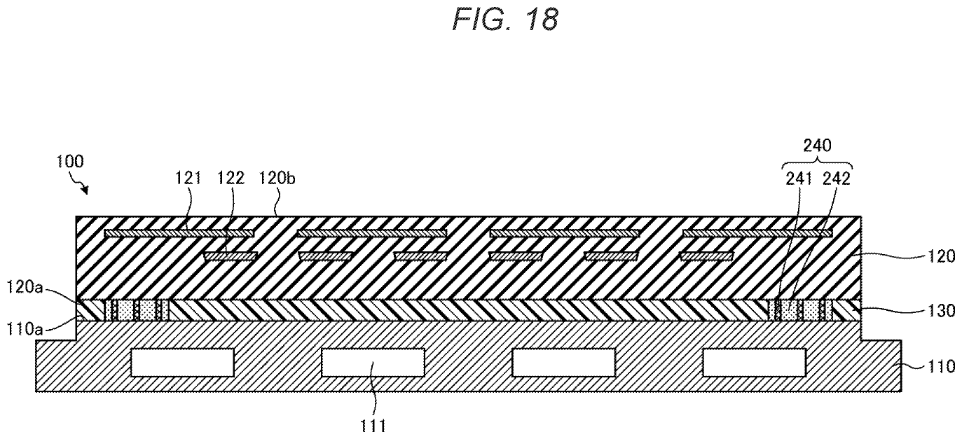

FIG. 17 shows a second modified embodiment of the substrate fixing device 100 according to the second embodiment. In FIG. 17, the same parts as those in FIG. 11 are denoted with the same reference signs.

In the modified embodiment shown in FIG. 17, the thermal conduction member 240 is arranged in an outer circumferential region of the adhesive surface (i.e., upper surface 110a) of the base plate 110 overlapping the outer circumferential portion of the ceramic plate 120 in a plan view, instead of the outer circumferential region R2 in the inside of the adhesive layer 130. Specifically, a concave portion 110b is formed in the outer circumferential region of the upper surface 110a of the base plate 110, and the thermal conduction member 240 is arranged in the concave portion 110b. The thermal conduction member 240 may be bonded to a bottom surface of the concave portion 110b via an adhesive 245, for example. In this way, even when the thermal conduction member 240 is arranged in the outer circumferential region of the upper surface 110a of the base plate 110, the temperature difference between the central region and the outer circumferential region on the adsorption surface of the ceramic plate 120 can be generated, and therefore, the controllability of the temperature distribution on the adsorption surface can be improved.

In the present embodiment, the case where the entire surface of the resin 242 of the thermal conduction member 240 is covered with the adhesive layer 130 has been described as an example, but only a side surface of the resin 242 may be covered with the adhesive layer 130.

FIG. 18 shows a third modified embodiment of the substrate fixing device 100 according to the second embodiment. In FIG. 18, the same parts as those in FIG. 11 are denoted with the same reference signs.

In the modified embodiment shown in FIG. 18, only the side surface of the resin 242 of the thermal conduction member 240 is covered with the adhesive layer 130, and an upper surface (an example of the first surface) and a lower surface (an example of the second surface) of the resin 242 are exposed from the adhesive layer 130. The upper surface of the resin 242 exposed from the adhesive layer 130 is bonded to the adhesive surface (i.e., lower surface 120a) of the ceramic plate 120, and the lower surface of the resin 242 exposed from the adhesive layer 130 is bonded to the adhesive surface (i.e., upper surface 110a) of the base plate 110. The carbon nanotubes 241 of the thermal conduction member 240 have the upper end surfaces exposed from the upper surface of the resin 242 and are thus in contact with the lower surface 120a of the ceramic plate 120, and have the lower end surfaces exposed from the lower surface of the resin 242 and are thus in contact with the upper surface 110a of the base plate 110. This makes it possible to smoothly transfer heat from the ceramic plate 120 to the base plate 110 via the thermal conduction member 240, resulting in further improvement in the control lability of the temperature distribution on the adsorption surface of the ceramic plate 120.

Note that, in the second embodiment and the respective modified embodiments thereof, the case where the thermal conduction member 240 is arranged in the adhesive surface of the ceramic plate 120, the adhesive surface of the base plate 110, or the inside of the adhesive layer 130 has been described as an example. However, the arrangement position of the thermal conduction member 240 can be changed as appropriate. For example, the thermal conduction member 240 may be arranged in any two of the adhesive surface of the ceramic plate 120, the adhesive surface of the base plate 110, and the inside of the adhesive layer 130. Further, the thermal conduction member 240 may be arranged in the adhesive surface of the ceramic plate 120, the adhesive surface of the base plate 110, and the inside of the adhesive layer 130. In short, the thermal conduction member 240 may be arranged in at least one of the adhesive surface of the ceramic plate 120, the adhesive surface of the base plate 110, and the inside of the adhesive layer 130.

This disclosure further encompasses various exemplary embodiments, for example, described below.

[1] A manufacturing method of a substrate fixing device, the manufacturing method comprising:
forming a ceramic plate having an electrode embedded in an outer circumferential portion for generating heat;
bonding a thermal conduction member, which has thermal conductivity in a stack direction of a base plate and the ceramic plate member higher than thermal conductivity in a plane direction perpendicular to the stack direction, to a central region of an adhesive surface of the ceramic plate overlapping a central portion of the ceramic plate in a plan view;
applying a second adhesive to an adhesive surface of the base plate; and
stacking the second adhesive on the adhesive surface of the ceramic plate to cover the thermal conduction member and the first adhesive and bonding the ceramic plate to the adhesive surface of the base plate via an adhesive layer having the first adhesive and the second adhesive.

[2] A manufacturing method of a central fixing device, the manufacturing method comprising:
forming a ceramic plate having an electrode embedded in a central portion for generating heat;
bonding a thermal conduction member, which has thermal conductivity in a stack direction of a base plate and the ceramic plate member higher than thermal conductivity in a plane direction perpendicular to the stack direction, to an outer circumferential region of an adhesive surface of the ceramic plate overlapping an outer circumferential portion of the ceramic plate in a plan view;
applying a second adhesive to an adhesive surface of the base plate; and
stacking the second adhesive on the adhesive surface of the ceramic plate to cover the thermal conduction member and the first adhesive and bonding the ceramic plate to the adhesive surface of the base plate via an adhesive layer having the first adhesive and the second adhesive.

What is claimed is:

1. A substrate fixing device comprising:
a base plate;
a ceramic plate bonded to the base plate via an adhesive layer and configured to adsorb a substrate by electrostatic force;
a thermal conduction member arranged in only a central region, which overlaps a central portion of the ceramic plate in a plan view, or in only an outer circumferential region, which overlaps an outer circumferential portion of the ceramic plate in a plan view of at least one of an adhesive surface of the ceramic plate, an adhesive surface of the base plate, or an inside of the adhesive layer, the thermal conduction member having thermal conductivity in a stack direction of the base plate and the ceramic plate member higher than thermal conductivity in a plane direction perpendicular to the stack direction.

2. The substrate fixing device according to claim 1, wherein the thermal conduction member comprises:
a carbon nanotube arranged such that a longitudinal direction is along the stack direction, and
a resin covering the carbon nanotube in a state in which both end surfaces of the carbon nanotube in the longitudinal direction are exposed.

3. The substrate fixing device according to claim 2, wherein the thermal conduction member is arranged in only the central region or in only the outer circumferential region in the inside of the adhesive layer,
wherein the resin has:
a first surface bonded to the adhesive surface of the ceramic plate,
a second surface bonded to the adhesive surface of the base plate; and
a side surface connecting the first surface and the second surface and covered by the adhesive layer, and
wherein the carbon nanotube has one end surface exposed from the first surface of the resin and in contact with the adhesive surface of the ceramic plate, and has the other end surface exposed from the second surface of the resin and in contact with the adhesive surface of the base plate.

4. The substrate fixing device according to claim 1, wherein the adhesive layer comprises:
a first adhesive bonding the thermal conduction member to the central region or outer circumferential region of the adhesive surface of the ceramic plate, and
a second adhesive stacked between the adhesive surface of the ceramic plate and the adhesive surface of the base plate and configured to cover the thermal conduction member and the first adhesive.

5. The substrate fixing device according to claim 4, wherein the first adhesive has thermal conductivity higher than that of the second adhesive.

6. The substrate fixing device according to claim 1, wherein the central region or outer circumferential region of at least one of the adhesive surface of the ceramic plate or the adhesive surface of the base plate is formed with a concave portion, and
wherein the thermal conduction member is arranged in the concave portion.

7. The substrate fixing device according to claim 1, wherein the thermal conduction member is arranged in the central region of at least one of the adhesive surface of the ceramic plate, the adhesive surface of the base plate, or the inside of the adhesive layer, and
wherein the ceramic plate has an electrode for generating heat embedded in the outer circumferential portion.

8. The substrate fixing device according to claim 1, wherein the thermal conduction member is arranged in the outer circumferential region of at least one of the adhesive surface of the ceramic plate, the adhesive surface of the base plate, or the inside of the adhesive layer, and
wherein the ceramic plate has an electrode for generating heat embedded in the central portion.
